(19) United States
(12) Patent Application Publication
(10) Pub. No.: US 2002/0101252 A1
(43) Pub. Date: Aug. 1, 2002

(54) Structure for capacitance measurement

(75) Inventors: Huang-Chung Cheng, Hsinchu (TW); Gwo-Yann Lee, Taichung (TW); Cheng-Jer Yang, Pingjen City (TW)

Correspondence Address: Skjerven, Morrill, Macpherson LLP, Suite 700, 25 Metro Drive, San Jose, CA, 95110, US

(73) Assignee: National Science Council

(21) Appl. No.: 09/846,736

(22) Filed: Apr. 30, 2001

(30) Foreign Application Priority Data
Jan. 31, 2001 (TW) 90101963

(51) Int. Cl. G01R 27/26

(52) U.S. Cl. 324/681

(57) ABSTRACT

A structure for being used in measuring a capacitance of a capacitor is provided. The structure includes a plurality of input terminals having an operating voltage and an operating frequency, a first quasi-inverting circuit having a first parasitic capacitor for generating a first current and electrically connected with the input terminals, a second quasi-inverting circuit having a second parasitic capacitor and a first reference capacitor for generating a second current and electrically connected with the first quasi-inverting circuit, and a third quasi-inverting circuit having the capacitor, a third parasitic capacitor and a second reference capacitor for generating a third current and electrically connected with the quasi-inverting circuit.

### FIELD OF THE INVENTION

The present invention relates to a structure, and more particularly to a structure for being used in measuring a capacitance.

### BACKGROUND OF THE INVENTION

In the prior art, the capacitance is obtained by integrating electric charges of a dielectric material. For low leakage current material, eg. silicon dioxide and silicon nitride, the capacitance thereof is not dramatically affected by the lost charges. However, for the material with low dielectric constant, the capacitance value is easily affected by the higher leakage current. Therefore, the influence of the leakage current on measuring the capacitance could not be neglected.

Because the integrated circuit density is increased, the design of multiple interconnecting lines is needed. However, the circuit characteristics are affected by the parasitic capacitance effect of the multiple interconnecting lines. Generally, the parasitic capacitance of the multiple interconnecting lines is ranged from 10⁻¹⁴ to 10⁻¹² F. In addition, for the material with low dielectric constant, the parasitic capacitance thereof is detected with difficulty by the capacitance measurement devices. In addition, the parasitic capacitance measurement of the multiple interconnecting line is difficult due to the small measurement structure and the leakage current of the insulating materials. Moreover, when the electric charges of the multiple interconnecting lines are changed with time, the parasitic capacitance value measured is not accurate.

In order to overcome the fore said problems, the present invention provide a structure and a method for measuring the parasitic capacitance of metal interconnecting lines.

### SUMMARY OF THE INVENTION

It is an object of the present invention to provide a structure for being used in measuring capacitance of a capacitor.

In accordance with the present invention, the structure includes a plurality of terminals, a first quasi-inverting circuit, a second quasi-inverting circuit and a third quasi-inverting circuit.

The plurality of input terminals have an operating voltage and an operating frequency.

The first quasi-inverting circuit has a first parasitic capacitor for generating a first current and electrically connected with the input terminals.

The second quasi-inverting circuit has a second parasitic capacitor and a first reference capacitor for generating a second current and electrically connected with the first quasi-inverting circuit.

The third quasi-inverting circuit has the capacitor, a third parasitic capacitor and a second reference capacitor for generating a third current and electrically connected with the quasi-inverting circuit.

In addition, the input terminals are in different phases. The first reference capacitor is connected in parallel to the second parasitic capacitor.

Preferably, the capacitor is connected with the second reference capacitor in series.

In accordance with the present invention, the capacitor is a fourth parasitic capacitor needed to be measured.

Preferably, the first parasitic capacitor, the second parasitic capacitor and the third parasitic capacitor are the same parasitic capacitors.

Preferably, each parasitic capacitor is made of a first material with low leakage current. The first material is silicon dioxide (SiO₂).

In addition, the first reference capacitor and the second reference capacitor are the same reference capacitors for reducing leakage current of the capacitor.

Preferably, each reference capacitance is made of a second material with low leakage current. The second material is silicon dioxide (SiO₂). Furthermore, the operating frequency is ranged from 100 kHz to 10 MHz. The operating voltage is ranged from 1 to 100 V.

It is another object of the present invention to provide a method for being used in a structure having plural input terminals, a first quasi-inverting circuit, a second quasi-inverting circuit and a third quasi-inverting circuit to measure capacitance of a capacitor.

In accordance with the present invention, the method includes steps of a) measuring a first current of the first quasi-inverting circuit, b) measuring a second current of the second quasi-inverting circuit, c) measuring a third current of the third quasi-inverting circuit, and d) calculating the capacitance according to the first current, the second current, the third current and a specific formula and reducing leakage current of the capacitance to obtain the capacitance.

In addition, the first quasi-inverting circuit further includes a first parasitic capacitor.

The quasi-inverting circuit further includes a second parasitic capacitor and a first reference capacitor.

The third quasi-inverting circuit further includes the capacitor, a third parasitic capacitor and a second reference capacitor.

Preferably, the first parasitic capacitor, the second parasitic capacitor and the parasitic capacitor are the same parasitic capacitors.

Preferably, the first reference capacitor and the second reference capacitor are the same reference capacitors for reducing leakage current of the capacitor.

In accordance with the present invention, the specific formula is represented by the formula of:

I₁=Cₚₐᵣf V_{dd}

I₂=(Cₚₐᵣ+C_{ref})f V_{dd}

I₃=(Cₚₐᵣ+C_{ref}//Cₓ)f V_{dd},

wherein I₁, is the first current, I₂ is the second current, I₃ is the third current, Cₚₐᵣ is the capacitance of the parasitic capacitor, C_{ref} is the capacitance of the reference capacitor, Cₓ is the capacitance of the capacitor, f is an operating frequency of the input terminals and V_{dd} is an operating voltage of the input terminals.

The present invention may best be understood through the following descriptions with reference to the accompanying drawings, in which:

### BRIEF DESCRIPTION OF THE DRAWINGS

FIG. 1 is a schematic view showing the structure for measuring a capacitance according to the preferred embodiment of the present invention.

### DETAILED DESCRIPTION OF THE PREFERRED EMBODIMENTS

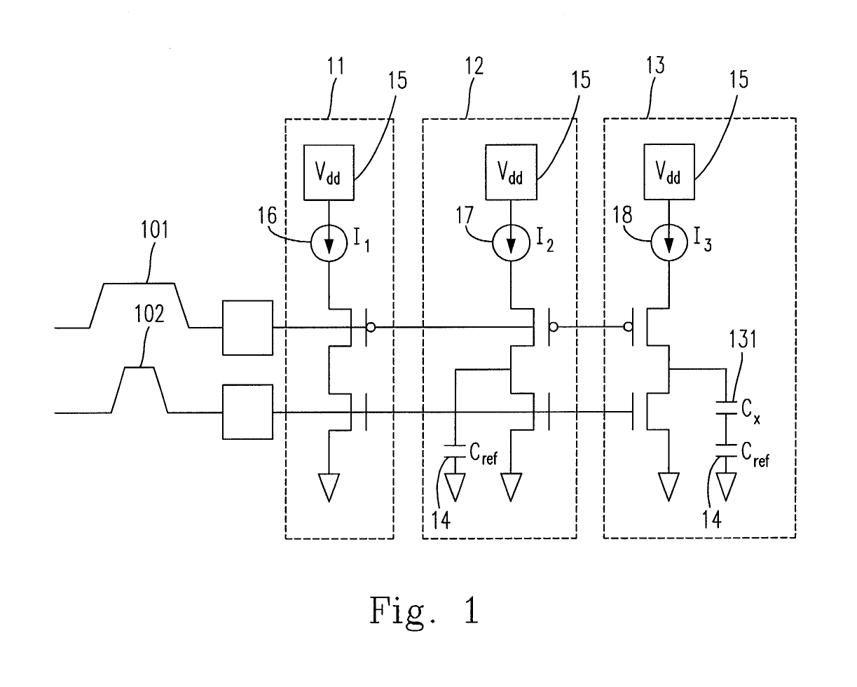

Please refer to FIG. 1. The structure provided by the present invention includes a first input terminal 101, a second input terminal 102, a first quasi-inverting circuit 11, a second quasi-inverting circuit 12 and a third quasi-inverting circuit 13. The structure is used for reducing the leakage current of a capacitor 131 and a parasitic capacitance of a transistor to accurately measure the capacitance of the capacitor 131.

The first input terminal 101 and the second input terminal 102 are in different phases and include an operating voltage V_{dd} 15 and an operating frequency f (not shown). The operating frequency f is ranged from 100 kHz to 10 MHz. The operating voltage V_{dd} is ranged from 1 to 100 V.

The first quasi-inverting circuit 11 is electrically connected with the first input terminal 101 and the second input terminal 102. The first quasi-inverting circuit 11 includes a first parasitic capacitor (not shown) to generate a first current I₁ 16. The second quasi-inverting circuit 12 is electrically connected with the first quasi-inverting circuit 11 and includes a first reference capacitor 14 connected in parallel to a second parasitic capacitor (not shown) to generate a second current I₂ 17.

The third quasi-inverting circuit 13 is electrically connected with the second quasi-inverting circuit 12 and includes the capacitor 131, a second reference capacitor and a third capacitor (not shown) to generate a third current I₃ 18. The capacitance 131 is connected with the second reference capacitor in series.

The capacitance Cₓ of the capacitor 131 is accurately measured by calculation according to a specific formula with the first current I₁, the second current I₂ and the third current I₃.

In addition, the first parasitic capacitor, the second parasitic capacitor and the third parasitic capacitor could be the same parasitic capacitors made of a material with low leakage current. The preferred material with low leakage current is silicon dioxide.

The first reference capacitor and the second reference capacitor could be the same reference capacitors 14 made of a material with low leakage current for reducing the leakage current of the capacitor 131. The preferred material with low leakage current is silicon dioxide.

The foresaid specific formula is represented by the formulas as follows.

I₁=Cₚₐᵣf V_{dd} (1)

I₂=(Cₚₐᵣ+C_{ref})f V_{dd} (2)

I₃=(Cₚₐᵣ+C_{ref}//Cₓ)f V_{dd} (3)

When the input terminals are activated, the first current I₁ of the first quasi-inverting circuit 11 is measured, and then the second current I₂ of the second quasi-inverting circuit 12 is measured. Subsequently, the third current I₃ of the second quasi-inverting circuit 13 is measured. The Cₚₐᵣ is the capacitance of the parasitic capacitor, and the Cref is the capacitance of the reference capacitor.

Then, the equation (4) is derived from (2)-(1) and shown as follows.

C_{ref}=(I₁−I₂)/f V_{dd} (4)

The equation (3) is substituted by the equation (1) and shown as follows.

C_{ref}//Cₓ=(I₃−I₁)f V_{dd}=k (5)

Then, the capacitance Cₓ of the capacitor 131 is obtained from equations (4) and (5).

Cₓ=k×C_{ref}/(C_{ref}−k),

wherein k is a constant of (I₃−I₁)f V_{dd}.

While the invention has been described in terms of what are presently considered to be the most practical and preferred embodiments, it is to be understood that the invention need not be limited to the disclosed embodiment. On the contrary, it is intended to cover various modifications and similar arrangements included within the spirit and scope of the appended claims which are to be accorded with the broadest interpretation so as to encompass all such modifications and similar structures. Therefore, the above description and illustration should not be taken as limiting the scope of the present invention which is defined by the appended claims.

What is claimed is:

1. A structure for being used in measuring a capacitance of a capacitor, comprising:
a plurality of input terminals having an operating voltage and an operating frequency;
a first quasi-inverting circuit having a first parasitic capacitor for generating a first current and electrically connected with said input terminals;
a second quasi-inverting circuit having a second parasitic capacitor and a first reference capacitor for generating a second current and electrically connected with said first quasi-inverting circuit; and
a third quasi-inverting circuit having said capacitor, a third parasitic capacitor and a second reference capacitor for generating a third current and electrically connected with said quasi-inverting circuit.

2. The structure according to claim 1, wherein said input terminals are in different phases.

3. The structure according to claim 1, wherein said first reference capacitor is connected in parallel to said second parasitic capacitor.

4. The structure according to claim 1, wherein said capacitor is connected with said second reference capacitor in series.

5. The structure according to claim 1, wherein said capacitor is a fourth parasitic capacitor needed to be measured.

6. The structure according to claim 1, wherein said first parasitic capacitor, said second parasitic capacitor and said third parasitic capacitor are the same parasitic capacitors.

7. The structure according to claim 6, wherein each said parasitic capacitor is made of a first material with low leakage current.

8. The structure according to claim 7, wherein said first material is silicon dioxide (SiO₂).

9. The structure according to claim 1, wherein said first reference capacitor and said second reference capacitor are the same reference capacitors for reducing leakage current of said capacitor.

10. The structure according to claim 9, wherein each said reference capacitor is made of a second material with low leakage current.

11. The structure according to claim 10, wherein said second material is silicon dioxide (SiO₂).

12. The structure according to claim 1, wherein said operating frequency is ranged from 100 kHz to 10 MHz.

13. The structure according to claim 1, wherein said operating voltage is ranged from 1 to 100 V.

14. A method for being used in a structure having plural input terminals, a first quasi-inverting circuit, a second quasi-inverting circuit and a third quasi-inverting circuit to measure a capacitance of a capacitor, comprising steps of:
a) measuring a first current of said first quasi-inverting circuit;
b) measuring a second current of said second quasi-inverting circuit;
c) measuring a third current of said third quasi-inverting circuit; and
d) calculating said capacitance according to said first current, said second current, said third current and a specific formula and reducing leakage current of said capacitor to obtain said capacitance of said capacitor.

15. The method according to claim 14, wherein said first quasi-inverting circuit further comprises a first parasitic capacitor.

16. The method according to claim 15, wherein said quasi-inverting circuit further comprises a second parasitic capacitor and a first reference capacitor.

17. The method according to claim 16, wherein said third quasi-inverting circuit further comprises said capacitor, a third parasitic capacitor and a second reference capacitor.

18. The method according to claim 17, wherein said first parasitic capacitor, said second parasitic capacitor and said third parasitic capacitor are the same parasitic capacitors.

19. The method according to claim 18, wherein said first reference capacitor and said second reference capacitor are the same reference capacitors for reducing leakage current of said capacitor.

20. The method according to claim 19, wherein said specific formula is represented by the formula of:
I₁=Cₚₐᵣf V_{dd}
I₂=(Cₚₐᵣ+C_{ref})f V_{dd}
I₃=(Cₚₐᵣ+C_{ref}//Cₓ)f V_{dd},
wherein I₁ is said first current, I₂ is said second current, I₃ is said third current, Cₚₐᵣ is the capacitance of said parasitic capacitor, C_{ref} is the capacitance of said reference capacitor, Cₓ is the capacitance of said capacitor, f is an operating frequency of said input terminals and V_{dd} is an operating voltage of said input terminals.
